(19) United States
(12) Patent Application Publication
(10) Pub. No.: US 2012/0326730 A1
(43) Pub. Date: Dec. 27, 2012

(54) SENSOR ASSEMBLY AND MICROWAVE EMITTER FOR USE IN A SENSOR ASSEMBLY

(76) Inventors: Steven Go, Schenectady, NY (US); Joseph Alfred Iannotti, Glenville, NY (US); Boris Leonid Sheikman, Minden, NV (US); Yongjae Lee, Niskayuna, NY (US)

(21) Appl. No.: 13/168,705

(22) Filed: Jun. 24, 2011

(51) Int. Cl. G01R 27/04

(52) U.S. Cl. 324/637

(57) ABSTRACT

A microwave probe for use in a microwave sensor assembly includes an emitter body and an emitter coupled to the emitter body. The emitter includes a first portion, a second portion, and a connecting portion coupling the first portion to the second portion. The first portion and the second portion generate an electromagnetic field when at least one microwave signal is received, and a loading is induced to the emitter when an object is positioned within the electromagnetic field.

### BACKGROUND OF THE INVENTION

The present application relates generally to power systems and, more particularly, to a sensor assembly and a microwave emitter for use in a sensor assembly.

Known machines may exhibit vibrations and/or other abnormal behavior during operation. One or more sensors may be used to measure and/or monitor such behavior and to determine, for example, an amount of vibration exhibited in a machine drive shaft, a rotational speed of the machine drive shaft, and/or any other operational characteristic of an operating machine or motor. Often, such sensors are coupled to a machine monitoring system that includes a plurality of monitors. The monitoring system receives signals from one or more sensors, performs at least one processing step on the signals, and transmits the modified signals to a diagnostic platform that displays the measurements to a user.

At least some known machines use eddy current sensors to measure the vibrations in and/or a position of a machine component. However, the use of known eddy current sensors may be limited because a detection range of such sensors is only about half of a diameter of the eddy current sensing element. Other known machines use optical sensors to measure a vibration and/or a position of a machine component. However, known optical sensors may become fouled by contaminants and provide inaccurate measurements, and as such, may be unsuitable for industrial environments. Further, known optical sensors may not be suitable for detecting a vibration and/or a position of a machine component through a liquid medium and/or a medium that includes particulates.

### BRIEF DESCRIPTION OF THE INVENTION

In one embodiment, a microwave probe for use in a microwave sensor assembly is provided that includes an emitter body and an emitter coupled to the emitter body. The emitter includes a first portion, a second portion, and a connecting portion coupling the first portion to the second portion. The first portion and the second portion generate an electromagnetic field when at least one microwave signal is received, and a loading is induced to the emitter when an object is positioned within the electromagnetic field.

In another embodiment, a microwave sensor assembly is provided that includes an emitter body and an emitter coupled to the emitter body. The emitter includes a first portion, a second portion, and a connecting portion coupling the first portion to the second portion. The first portion and the second portion generate an electromagnetic field when at least one microwave signal is received. The microwave sensor assembly also includes a signal processing device coupled to the emitter for transmitting at least one microwave signal to the emitter and for calculating a proximity measurement based on a signal received from the emitter.

In yet another embodiment, a method for measuring a proximity of a machine component relative to an emitter is provided. The method includes transmitting at least one microwave signal to the emitter that includes a first portion, a second portion, and a connecting portion coupling the first portion to the second portion. The first portion and the second portion generate an electromagnetic field when at least one microwave signal is received. The method also includes generating an electromagnetic field from the at least one microwave signal, generating a loading signal representative of a disruption of the electromagnetic field, and calculating the proximity of the machine component to the emitter based on the loading signal.

### BRIEF DESCRIPTION OF THE DRAWINGS

FIG. 1 is a block diagram of an exemplary power system.

FIG. 2 is a block diagram of an exemplary sensor assembly that may be used with the power system shown in FIG. 1.

FIG. 3 is a perspective view of an exemplary emitter body that may be used with the sensor assembly shown in FIG. 2.

FIG. 4 is a front view of an exemplary microwave emitter that may be used with the sensor assembly shown in FIG. 2.

FIG. 5 is a front view of another exemplary microwave emitter that may be used with the sensor assembly shown in FIG. 2.

FIG. 6 is a front view of yet another exemplary microwave emitter that may be used with the sensor assembly shown in FIG. 2.

FIG. 7 is a front view of another exemplary microwave emitter that may be used with the sensor assembly shown in FIG. 2.

### DETAILED DESCRIPTION OF THE INVENTION

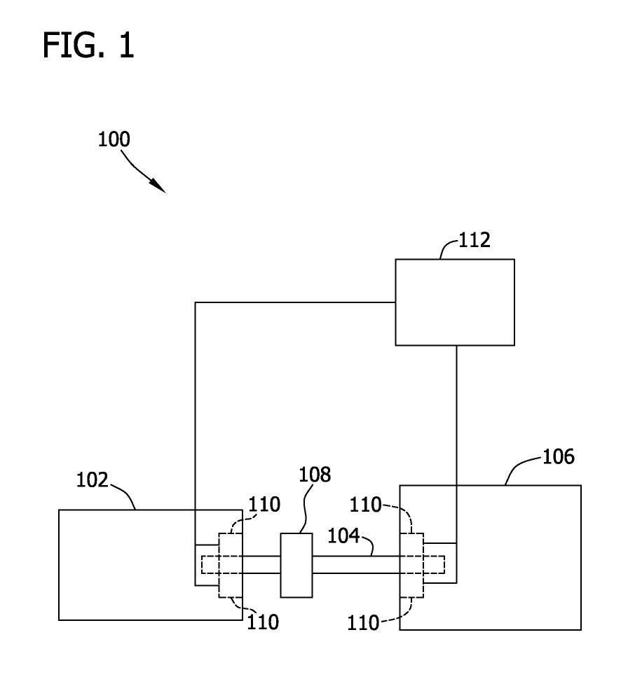

FIG. 1 shows an exemplary power system 100 that includes a machine 102. In the exemplary embodiment, machine 102 may be, but is not limited to only being, a wind turbine, a hydroelectric turbine, a gas turbine, or a compressor. Alternatively, machine 102 may be any other machine used in a power system. In the exemplary embodiment, machine 102 rotates a drive shaft 104 coupled to a load 106, such as a generator.

In the exemplary embodiment, drive shaft 104 is at least partially supported by one or more bearings (not shown) housed within machine 102 and/or within load 106. Alternatively or additionally, the bearings may be housed within a separate support structure 108, such as a gearbox, or within any other structure or component that enables power system 100 to function as described herein.

In the exemplary embodiment, power system 100 includes at least one sensor assembly 110 that measures and/or monitors at least one operating condition of machine 102, of drive shaft 104, of load 106, and/or of any other component of power system 100 that enables system 100 to function as described herein. More specifically, in the exemplary embodiment, sensor assembly 110 is a proximity sensor assembly 110 positioned in close proximity to drive shaft 104 for measuring and/or monitoring a distance (not shown in FIG. 1) defined between drive shaft 104 and sensor assembly 110. In the exemplary embodiment, sensor assembly 110 uses microwave signals to measure a proximity, such as a static and/or vibration proximity, of a component of power system 100 with respect to sensor assembly 110. As used herein, the term “microwave” refers to a signal or a component that receives and/or transmits signals having one or more frequencies between about 300 Megahertz (MHz) and about 300 Gigahertz (GHz). Alternatively, sensor assembly 110 may measure and/or monitor any other component of power system 100, and/or may be any other sensor or transducer assembly that enables power system 100 to function as described herein. In the exemplary embodiment, each sensor assembly 110 is positioned in any location within power system 100. Further, in the exemplary embodiment, at least one sensor assembly 110 is coupled to a diagnostic system 112 for use in processing and/or analyzing one or more signals generated by sensor assemblies 110.

During operation, in the exemplary embodiment, the operation of machine 102 may cause one or more components of power system 100, such as drive shaft 104, to change position with respect to at least one sensor assembly 110. For example, vibrations may be induced to the components and/or the components may expand or contract as the operating temperature within power system 100 changes. In the exemplary embodiment, sensor assemblies 110 measure and/or monitor the proximity and/or the position of the components relative to each sensor assembly 110 and transmit a signal representative of the measured proximity and/or position of the components (hereinafter referred to as a “proximity measurement signal”) to diagnostic system 112 for processing and/or analysis.

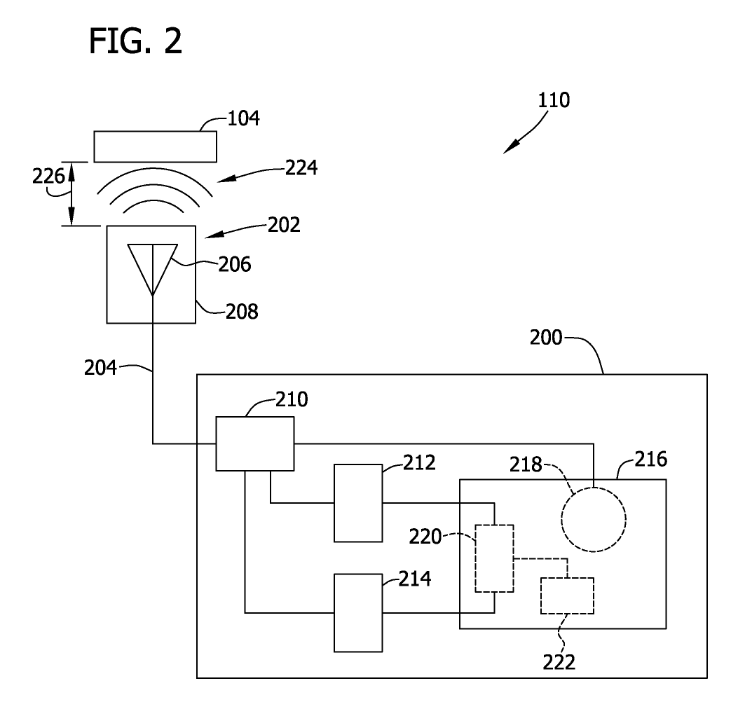

FIG. 2 is a schematic diagram of an exemplary sensor assembly 110 that may be used with power system 100 (shown in FIG. 1). In the exemplary embodiment, sensor assembly 110 includes a signal processing device 200 and a probe 202 coupled to signal processing device 200 by a data conduit 204. In the exemplary embodiment, probe 202 includes an emitter 206 coupled to and/or positioned within a probe housing 208. More specifically, in the exemplary embodiment, probe 202 is a microwave probe 202 that includes a microwave emitter 206. As such, in the exemplary embodiment, emitter 206 has at least one resonant frequency within a microwave frequency range.

In the exemplary embodiment, signal processing device 200 includes a directional coupling device 210 coupled to a transmission power detector 212, to a reception power detector 214, and to a signal conditioning device 216. In the exemplary embodiment, signal conditioning device 216 includes a signal generator 218, a subtractor 220, and a linearizer 222. Emitter 206 emits an electromagnetic field 224 when a microwave signal is transmitted through emitter 206.

During operation, in the exemplary embodiment, signal generator 218 generates at least one electrical signal having a microwave frequency (hereinafter referred to as a “microwave signal”) that is equal or approximately equal to the resonant frequency of emitter 206. Signal generator 218 transmits the microwave signal to directional coupling device 210. Directional coupling device 210 separates the microwave signal and transmits or directs at least a portion of the microwave signal to transmission power detector 212 and transmits or directs the remaining portion of the microwave signal to emitter 206. As the microwave signal is transmitted through emitter 206, electromagnetic field 224 is emitted from emitter 206 and out of probe housing 208. If an object, such as a drive shaft 104 or another component of machine 102 (shown in FIG. 1) and/or of power system 100 enters and/or changes a relative position within electromagnetic field 224, an electromagnetic coupling may occur between the object and field 224. More specifically, because of the presence of the object within electromagnetic field 224 and/or because of such object movement, electromagnetic field 224 may be disrupted, for example, because of an induction and/or capacitive effect induced within the object that may cause at least a portion of electromagnetic field 224 to be inductively and/or capacitively coupled to the object as an electrical current and/or charge. In such an instance, emitter 206 is detuned (i.e., a resonant frequency of emitter 206 is reduced and/or changed) and a loading is induced to emitter 206. The loading induced to emitter 206 causes a reflection of the microwave signal (hereinafter referred to as a “detuned loading signal”) to be transmitted through data conduit 204 to directional coupling device 210. In the exemplary embodiment, the detuned loading signal has a lower power amplitude and/or a different phase than the power amplitude and/or the phase of the microwave signal. Further, in the exemplary embodiment, the power amplitude of the detuned loading signal is dependent upon the proximity of the object to emitter 206. Directional coupling device 210 separates the detuned loading signal and transmits or directs at least a portion of the detuned loading signal to reception power detector 214 and transmits or directs the remaining portion of the detuned loading signal to signal generator 218.

In the exemplary embodiment, reception power detector 214 determines an amount of power based on and/or contained within the detuned loading signal and transmits a signal representative of the detuned loading signal power to signal conditioning device 216. Transmission power detector 212 determines an amount of power based on and/or contained within the microwave signal and transmits a signal representative of the microwave signal power to signal conditioning device 216. In the exemplary embodiment, subtractor 220 receives the microwave signal power and the detuned loading signal power, and calculates a difference between the microwave signal power and the detuned loading signal power. Subtractor 220 transmits a signal representative of the calculated difference (hereinafter referred to as a “power difference signal”) to linearizer 222. In the exemplary embodiment, an amplitude of the power difference signal is proportional, such as inversely or exponentially proportional, to a distance 226 defined between the object, such as drive shaft 104, within electromagnetic field 224 and probe 202 and/or emitter 206 (i.e., distance 226 is known as the object proximity). Depending on the characteristics of emitter 206, such as, for example, the geometry of emitter 206, the amplitude of the power difference signal may at least partially exhibit a non-linear relationship with respect to the object proximity.

In the exemplary embodiment, linearizer 222 transforms the power difference signal into a voltage output signal (i.e., the “proximity measurement signal”) that exhibits a substantially linear relationship between the object proximity and the amplitude of the proximity measurement signal. Further, in the exemplary embodiment, linearizer 222 transmits the proximity measurement signal to diagnostic system 112 (shown in FIG. 1) with a scale factor suitable for processing and/or analysis within diagnostic system 112. In the exemplary embodiment, the proximity measurement signal has a scale factor of volts per millimeter. Alternatively, the proximity measurement signal may have any other scale factor that enables diagnostic system 112 and/or power system 100 to function as described herein.

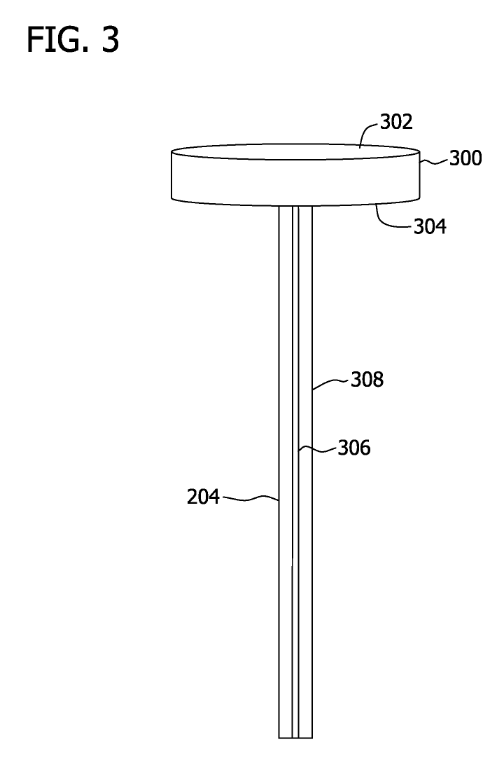

FIG. 3 is a perspective view of an exemplary emitter body 300 and data conduit 204 that may be used with sensor assembly 110. In the exemplary embodiment, emitter body 300 is positioned within, and/or is coupled to, probe housing 208 (shown in FIG. 2). Further, emitter 206 (shown in FIG. 2) is coupled to emitter body 300.

In the exemplary embodiment, emitter body 300 includes a front surface 302 and an opposing rear surface 304. Emitter 206 is coupled to, and/or is formed integrally with, front surface 302. More specifically, in the exemplary embodiment, emitter body 300 is a substantially planar printed circuit board, and emitter 206 includes one or more traces or conductors (not shown in FIG. 3) that are formed integrally with, and/or coupled to, emitter body front surface 302. In the exemplary embodiment, the traces or conductors are manufactured from copper and/or from any other conductive material that enables emitter 206 to function as described herein. Alternatively, emitter 206 and/or emitter body 300 may be configured and/or constructed in any other arrangement that enables sensor assembly 110 to function as described herein.

In the exemplary embodiment, data conduit 204 includes an inner conductor 306 and an outer conductor 308 that substantially encloses inner conductor 306 such that conductors 306 and 308 are coaxial. Data conduit 204, in the exemplary embodiment, is a semi-rigid cable 204 that couples emitter 206 to signal processing device 200 (shown in FIG. 2). Alternatively, data conduit 204 is any other cable or conduit that enables sensor assembly 110 to function as described herein. In the exemplary embodiment, inner conductor 306 and outer conductor 308 are coupled to emitter body 300 and/or to emitter 206 to enable microwave signals to be transmitted from signal processing device 200 through emitter 206.

During operation, at least one microwave signal is transmitted to emitter 206 through inner conductor 306 and outer conductor 308. As the microwave signal is transmitted through emitter 206, an electromagnetic field 224 (shown in FIG. 2) is emitted. A proximity measurement is determined based on a loading induced to emitter 206, as described more fully above.

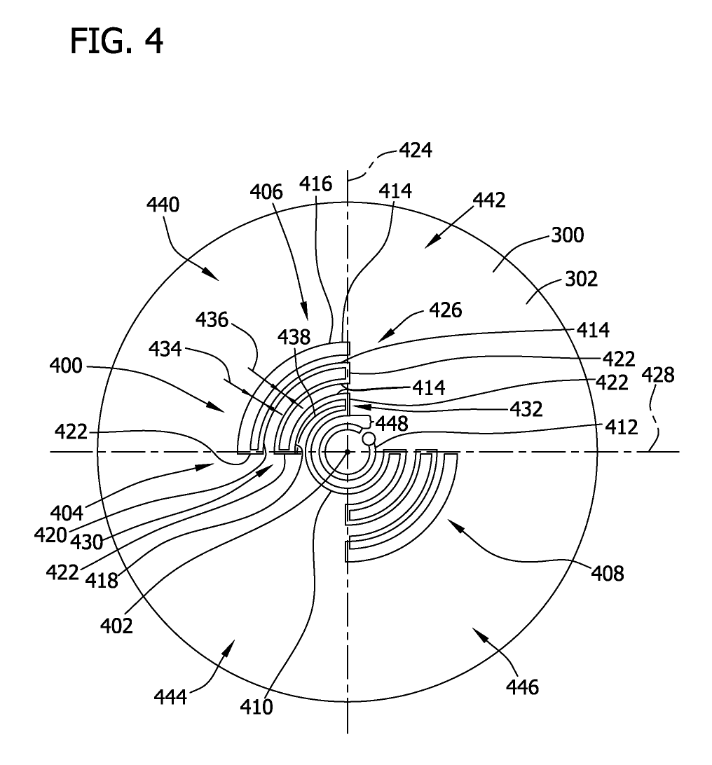

FIG. 4 is a front view of an exemplary microwave emitter 400 that may be used with sensor assembly 110 (shown in FIG. 2). Emitter 400, in the exemplary embodiment, is coupled to front surface 302 of emitter body 300 and extends radially outward from a center 402 of front surface 302. In the exemplary embodiment, emitter 400 includes a plurality of conductors 404, or traces, that are formed integrally with, and/or coupled to, emitter body front surface 302.

In the exemplary embodiment, emitter 400 includes a first portion 406, a second portion 408, and a connecting portion 410 that couples first portion 406 to second portion 408. Emitter 400 also includes an inner portion 412 that is substantially enclosed by first portion 406, second portion 408, and connecting portion 410. In the exemplary embodiment, first portion 406, second portion 408, connecting portion 410, and inner portion 412 are substantially coplanar with front surface 302 such that emitter 400 does not extend a substantial distance axially outward from front surface 302. Alternatively, emitter 400 and/or emitter body 300 may include any number of emitter portions and/or may be any shape that enables microwave sensor assembly 110 to function as described herein.

First portion 406, in the exemplary embodiment, includes a plurality of substantially arc-shaped segments 414 that are concentrically aligned with each other about center 402. Alternatively, segments 414 may have any other shape or configuration that enables emitter 400 to function as described herein. In the exemplary embodiment, segments 414 include a radially outermost segment 416 and a radially innermost segment 418. In the exemplary embodiment, segments 414 also include at least one middle segment 420 coupled to radially outermost segment 416 and/or to radially innermost segment 418. Each segment 414 is radially aligned with center 402 and is coupled to a neighboring segment 414 by at least one segment end 422. Each segment end 422 is alternately spaced with respect to each other segment end 422. More specifically, a first radius 424 extends through center 402 along a first edge 426 of first portion 406, and a second radius 428 extends through center 402 along a second edge 430 of first portion 406. In the exemplary embodiment, segment end 422 at a radially inner end 432 of first portion 406 is positioned substantially against first radius 424, and the next radially outer segment end 422 is positioned substantially against second radius 428. Subsequent radially outer segment ends 422 are positioned alternatingly against first radius 424 and second radius 428.

In the exemplary embodiment, radially outermost segment 416 has a width 434 that is greater than a width 436 of each other segment 414. In addition, segments 414 increase in length as segments 414 are spaced at an increasing radial distance from center 402. More specifically, radially innermost segment 418 has an arc length 438 that is smaller than an arc length 438 of middle segment 420, and middle segment arc length 438 is smaller than an arc length 438 of radially outermost segment 416.

Second portion 408, in the exemplary embodiment, is substantially similar to first portion 406. Accordingly, segments 414 and segment ends 422 of second portion 408 are substantially similar to segments 414 and segment ends 422 of first portion 406.

It should be recognized that modifications may be made to the shape and/or configuration of first portion 406 and/or second portion 408. For example, first portion 406 and/or second portion 408 may include any number of segments 414 and/or segment ends 422. Further, first radius 424 and second radius 428 divide front surface 302 into a first quadrant 440, a second quadrant 442, a third quadrant 444, and a fourth quadrant 446. While first portion 406 is illustrated as being positioned within first quadrant 440, first portion 406 may alternatively extend into second quadrant 442, third quadrant 444, and/or fourth quadrant 446. In addition, while second portion 408 is illustrated as being positioned within fourth quadrant 446, second portion 408 may alternatively extend into first quadrant 440, second quadrant 442, and/or third quadrant 444.

In the exemplary embodiment, connecting portion 410 is substantially circular and/or substantially arc-shaped, and is positioned about center 402. Connecting portion 410 electrically couples radially inner end 432 of first portion 406 to radially inner end 432 of second portion 408.

Inner portion 412, in the exemplary embodiment, is substantially circular and is positioned about center 402. Inner portion 412 is coupled to inner conductor 306 of data conduit 204 (both shown in FIG. 3), and outer conductor 308 (shown in FIG. 3) of data conduit 204 is coupled to first portion 406 and/or to second portion 408. In the exemplary embodiment, inner portion 412 is substantially enclosed or surrounded by first portion 406, second portion 408, and connecting portion 410. Further, inner portion 412 is spaced from first portion 406, second portion 408, and connecting portion 410 by a gap 448. In the exemplary embodiment, inner portion 412 is capacitively coupled to first portion 406, second portion 408, and connecting portion 410 when a signal, such as a microwave signal, is transmitted through inner portion 412.

During operation, at least one microwave signal is transmitted to emitter 400 through data conduit 204. The microwave signal is transmitted to inner portion 412 by inner conductor 306. As the microwave signal is transmitted through inner portion 412, a capacitive coupling occurs between inner portion 412 and first portion 406, second portion 408, and connecting portion 410. The capacitive coupling across gap 448 induces a current through first portion 406, second portion 408, and connecting portion 410 such that an electromagnetic field 224 (shown in FIG. 2) is emitted from emitter 400 (i.e., from portions 406, 408, 410, and 412). The current in first portion 406, second portion 408, and/or connecting portion 410 is returned to signal processing device 200 through outer conductor 308. A proximity measurement is determined based on a loading induced to emitter 400, as described more fully above. The radially spaced segments 414 of first portion 406 and second portion 408, and the capacitive coupling between inner portion 412 and first portion 406, second portion 408, and connecting portion 410, facilitate providing frequency stability such that emitter 400 may be controllably and/or predictably detuned by the presence and/or relative movement of an object with respect to emitter 400.

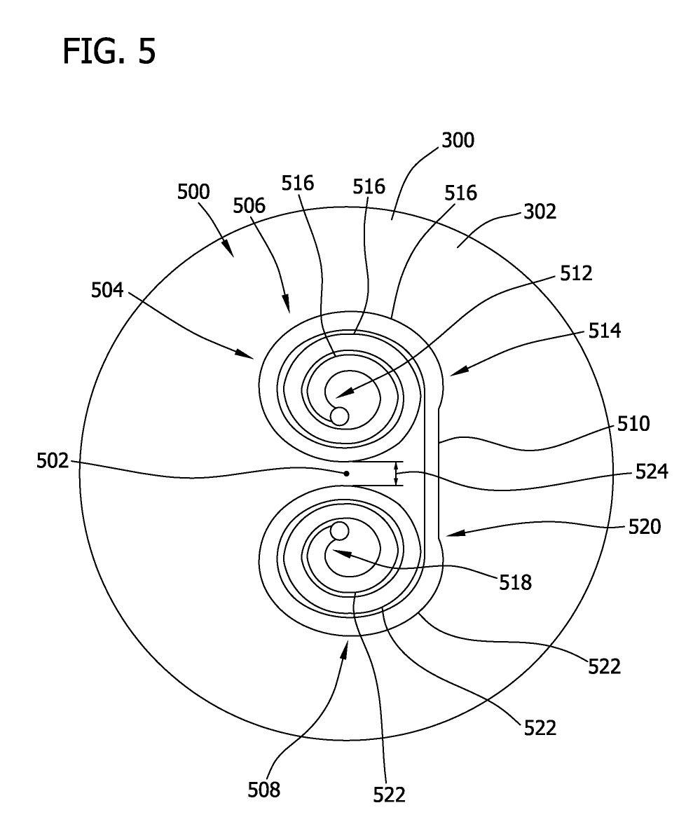

FIG. 5 is a front view of another exemplary microwave emitter 500 that may be used with sensor assembly 110 (shown in FIG. 2). Emitter 500, in the exemplary embodiment, is coupled to front surface 302 of emitter body 300 and extends radially outward from a center 502 of front surface 302. In the exemplary embodiment, emitter 500 includes a plurality of conductors 504, or traces, formed integrally with, and/or coupled to, emitter body front surface 302. Alternatively, emitter 500 includes a single conductor 504 formed integrally with, and/or coupled to, emitter body front surface 302.

In the exemplary embodiment, emitter 500 includes a first portion 506, a second portion 508, and a connecting portion 510 that couples first portion 506 to second portion 508. In the exemplary embodiment, first portion 506, second portion 508, and connecting portion 510 are substantially coplanar with front surface 302 such that emitter 500 does not extend a substantial distance axially outward from front surface 302. Alternatively, emitter 500 and/or emitter body 300 may include any number of emitter portions and/or may be any shape that enables microwave sensor assembly 110 to function as described herein.

First portion 506 includes a radially inner end 512 and a radially outer end 514. First portion 506 also includes a plurality of radially spaced, substantially circular segments 516 that extend in a substantially spiral shape in a first, or clockwise, direction from radially inner end 512 to radially outer end 514. Second portion 508 includes a radially inner end 518 and a radially outer end 520. Second portion 508 also includes a plurality of radially spaced, substantially circular segments 522 that extend in a substantially spiral shape in a second direction different from the first direction (i.e., a counter-clockwise direction) from radially inner end 518 to radially outer end 520.

In the exemplary embodiment, radially inner end 512 of first portion 506 is coupled to inner conductor 306 of data conduit 204 (both shown in FIG. 3) and radially inner end 518 of second portion 508 is coupled to outer conductor 308 of data conduit 204. In an alternative embodiment, radially inner end 512 of first portion 506 is coupled to outer conductor 308 and radially inner end 518 of second portion 508 is coupled to inner conductor 306. In another embodiment, outer conductor 308 is not coupled to radially inner end 512 of first portion 506 or radially inner end 518 of second portion 508. In such an embodiment, emitter 500 may exhibit less frequency stability than the exemplary embodiment.

Connecting portion 510, in the exemplary embodiment, is substantially linear. Connecting portion 510 electrically couples radially outer end 514 of first portion 506 to radially outer end 520 of second portion 508. In addition, connecting portion 510 separates first portion 506 from second portion 508 such that a gap 524 is defined between first portion 506 and second portion 508.

In an alternative embodiment, segments 522 of second portion 508 extend in a substantially spiral shape in the first direction (i.e., the clockwise direction) from radially inner end 518 to radially outer end 520. In such an embodiment, connecting portion 510 extends substantially diagonally across front surface 302 (with respect to a centerline (not shown) bisecting first portion 506 and second portion 508) to couple radially outer end 514 of first portion 506 to radially outer end 520 of second portion 508.

During operation, at least one microwave signal is transmitted to emitter 500 by data conduit 204. The microwave signal is transmitted to radially inner end 512 of first portion 506 by inner conductor 306. The microwave signal is transmitted through first portion 506 in the clockwise direction, through connecting portion 510, and through second portion 508 in the clockwise direction. As the microwave signal is transmitted through emitter 500, an electromagnetic field 224 (shown in FIG. 2) is emitted (e.g., from portions 506, 508, and 510). The current in first portion 506, second portion 508, and/or connecting portion 510 is returned to signal processing device 200 through radially inner end 518 of second portion 508 and through outer conductor 308. A proximity measurement is determined based on a loading induced to emitter 500, as described more fully above. The substantially spiral pattern of emitter 500 provides an increased electrical length within a compact emitter body 300 as compared to prior art emitters. Further, the spiral pattern of emitter 500 facilitates emitting an increased amount of electromagnetic energy to electromagnetic field 224 as compared to prior art emitters. The radially spaced segments 516 and 522 of first portion 506 and second portion 508 facilitate providing frequency stability such that emitter 500 may be controllably and/or predictably detuned by the presence and/or relative movement of an object with respect to emitter 500.

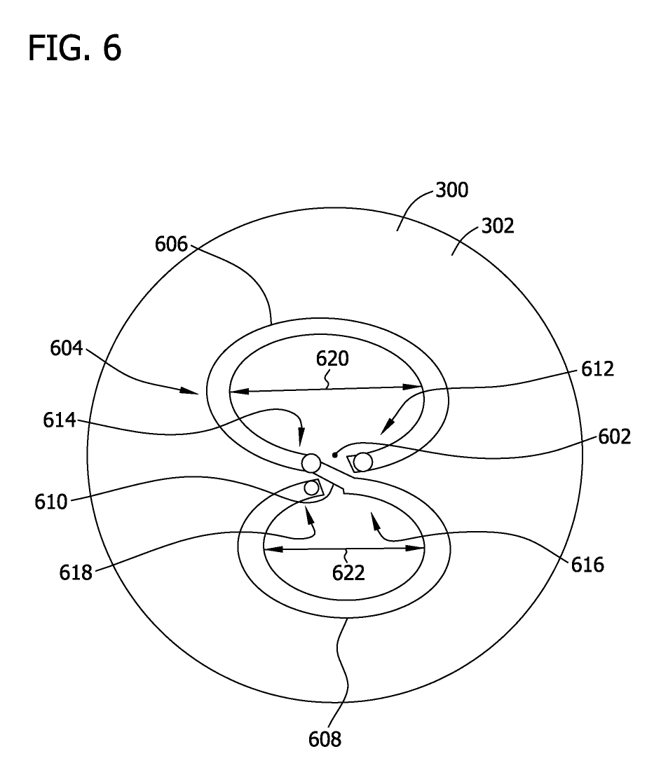

FIG. 6 is a front view of yet another exemplary microwave emitter 600 that may be used with sensor assembly 110 (shown in FIG. 2). Emitter 600, in the exemplary embodiment, is coupled to front surface 302 of emitter body 300 and extends radially outward from a center 602 of front surface 302. In the exemplary embodiment, emitter 600 includes a plurality of conductors 604, or traces, formed integrally with, and/or coupled to, emitter body front surface 302. Alternatively, emitter 600 includes a single conductor 604 formed integrally with, and/or coupled to, emitter body front surface 302.

In the exemplary embodiment, emitter 600 includes a first portion 606, a second portion 608, and a connecting portion 610 that couples first portion 606 to second portion 608. In the exemplary embodiment, first portion 606, second portion 608, and connecting portion 610 are substantially coplanar with front surface 302 such that emitter 600 does not extend a substantial distance axially outward from front surface 302. Alternatively, emitter 600 and/or emitter body 300 may include any number of emitter portions and/or may be any shape that enables microwave sensor assembly 110 to function as described herein.

First portion 606 includes a first end 612 and a second end 614. First portion 606 extends in a substantially circular shape in a first, or counter-clockwise, direction from first end 612 to second end 614 to form a first loop. Second portion 608 includes a first end 616 and a second end 618. Second portion 608 extends in a substantially circular shape in a second direction different from the first direction (i.e., a clockwise direction) from first end 616 to second end 618 to form a second loop. Further, a diameter 620 of first portion 606 is different than (e.g., is greater than) a diameter 622 of second portion 608.

In the exemplary embodiment, first end 612 of first portion 606 is coupled to inner conductor 306 of data conduit 204 (both shown in FIG. 3) and second end 618 of second portion 608 is coupled to outer conductor 308 of data conduit 204. In an alternative embodiment, first end 612 of first portion 606 is coupled to outer conductor 308 and second end 618 of second portion 608 is coupled to inner conductor 306.

Connecting portion 610, in the exemplary embodiment, is substantially linear. Connecting portion 610 electrically couples second end 614 of first portion 606 to first end 616 of second portion 608.

During operation, at least one microwave signal is transmitted to emitter 600 by data conduit 204. The microwave signal is transmitted to first end 612 of first portion 606 by inner conductor 306. The microwave signal is transmitted through first portion 606 in the counter-clockwise direction, through connecting portion 610, and through second portion 608 in the clockwise direction. As the microwave signal is transmitted through emitter 600, an electromagnetic field 224 (shown in FIG. 2) is emitted (e.g., from portions 606, 608, and 610). The current in first portion 606, second portion 608, and/or connecting portion 610 is returned to signal processing device 200 (shown in FIG. 2) through second end 618 of second portion 608 and through outer conductor 308. A proximity measurement is determined based on a loading induced to emitter 600, as described more fully above. The circular or loop shape of emitter 600 facilitates providing frequency stability such that emitter 600 may be controllably and/or predictably detuned by the presence and/or relative movement of an object with respect to emitter 600. Further, the circular or loop shape of emitter 600 enables emitter 600 to detect and/or receive a change in frequency, in addition to a change in magnitude, of the signal returned to signal processing device 200 as object 104 (shown in FIG. 1) changes position with respect to emitter 600. The frequency and/or magnitude change may be used by signal processing device 200 to determine the proximity of object 104 with respect to emitter 600.

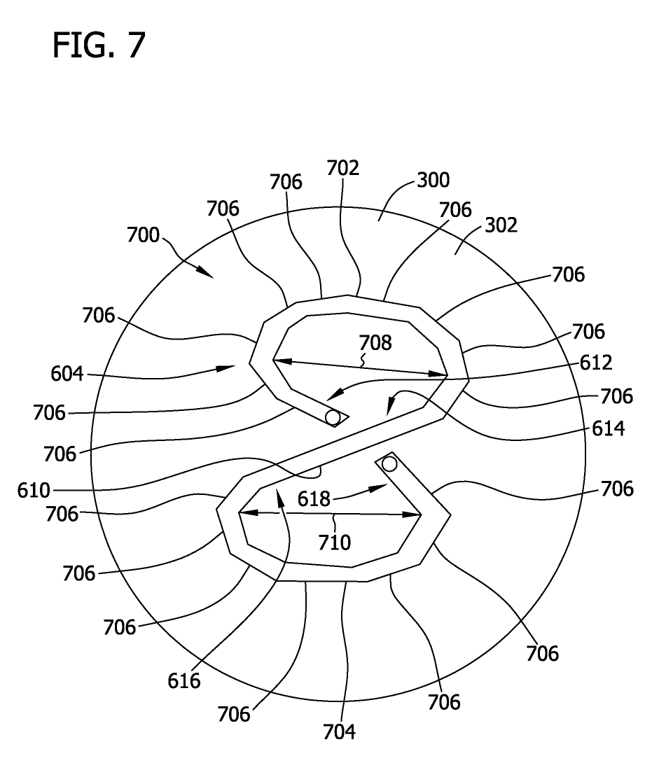

FIG. 7 is a front view of another exemplary microwave emitter 700 that may be used with sensor assembly 110 (shown in FIG. 2). Unless otherwise specified, emitter 700 is similar to emitter 600 (shown in FIG. 6), and similar components are labeled in FIG. 7 with the same reference numerals used in FIG. 6.

Emitter 700 has a similar shape as emitter 600 except that emitter 700 includes a first portion 702 and a second portion 704 that each includes a plurality of substantially linear segments 706. Linear segments 706 of first portion 702 form a substantially polygonal loop that has a first diameter 708. Linear segments 706 of second portion 704 form a substantially polygonal loop that has a second diameter 710 that is different from first diameter 708. Further, linear segments 706 of first portion 702 and of second portion 704 facilitate emitting additional radiation as compared to emitter 600. In addition, first portion 702 extends in a substantially circular shape in a first, or clockwise, direction from first end 612 to second end 614 to form a loop with linear segments 706. Second portion 704 extends in a substantially circular shape in a second direction different from the first direction (i.e., a counter-clockwise direction) from first end 616 to second end 618 to form a loop with linear segments 706. In other respects, emitter 700 functions substantially similar to emitter 600.

The above-described embodiments provide an efficient and cost-effective sensor assembly for use in measuring the proximity of a machine component. The sensor assembly energizes an emitter with a microwave signal. The emitter includes a first portion and a second portion that are coupled together by a connecting portion. When an object, such as a machine component, is positioned within the field, a loading is induced to the emitter due to a disruption of the field. The sensor assembly calculates a proximity of the object to the emitter based on the loading induced to the emitter. The shapes and/or configurations of the microwave emitters described herein facilitate providing a frequency stable electromagnetic field for use in measuring the proximity between the object and the emitter.

Exemplary embodiments of a sensor assembly and a microwave emitter are described above in detail. The sensor assembly and emitter are not limited to the specific embodiments described herein, but rather, components of the sensor assembly and/or the emitter may be utilized independently and separately from other components and/or steps described herein. For example, the emitter may also be used in combination with other measuring systems and methods, and is not limited to practice with only the sensor assembly or the power system as described herein. Rather, the exemplary embodiment can be implemented and utilized in connection with many other measurement and/or monitoring applications.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A microwave probe for use in a microwave sensor assembly, said microwave probe comprising:
an emitter body; and
an emitter coupled to said emitter body, said emitter comprising:
a first portion;
a second portion; and
a connecting portion coupling said first portion to said second portion, wherein said first portion and said second portion generate an electromagnetic field when at least one microwave signal is received, and wherein a loading is induced to said emitter when an object is positioned within the electromagnetic field.

2. A microwave probe in accordance with claim 1, wherein at least one of said first portion and said second portion has a substantially spiral shape.

3. A microwave probe in accordance with claim 1, wherein said first portion extends in a substantially spiral shape in a first direction, and said second portion extends in a substantially spiral shape in a second direction different from the first direction.

4. A microwave probe in accordance with claim 1, wherein each of said first portion and said second portion forms a substantially circular loop.

5. A microwave probe in accordance with claim 4, wherein a diameter of said first portion is different than a diameter of said second portion.

6. A microwave probe in accordance with claim 1, wherein said emitter further comprises an inner portion, said first portion and said second portion substantially enclose said inner portion.

7. A microwave probe in accordance with claim 6, wherein said inner portion is capacitively coupled to said first portion and to said second portion when the at least one microwave signal is transmitted through said inner portion.

8. A microwave probe in accordance with claim 1, wherein said emitter body is substantially planar, said first portion and said second portion extend along a surface of said emitter body.

9. A microwave sensor assembly comprising:
an emitter body;
an emitter coupled to said emitter body, said emitter comprising:
a first portion;
a second portion; and
a connecting portion coupling said first portion to said second portion, wherein said first portion and said second portion generate an electromagnetic field when at least one microwave signal is received; and
a signal processing device coupled to said emitter for transmitting at least one microwave signal to said emitter and for calculating a proximity measurement based on a signal received from said emitter.

10. A microwave sensor assembly in accordance with claim 9, further comprising a data conduit that couples said emitter to said signal processing device, said data conduit comprises an inner conductor and an outer conductor.

11. A microwave sensor assembly in accordance with claim 10, wherein said inner conductor is coupled to said first portion and said outer conductor is coupled to said second portion.

12. A microwave sensor assembly in accordance with claim 9, wherein at least one of said first portion and said second portion has a substantially spiral shape.

13. A microwave sensor assembly in accordance with claim 9, wherein said first portion extends in a substantially spiral shape in a first direction, and said second portion extends in a substantially spiral shape in a second direction different from the first direction.

14. A microwave sensor assembly in accordance with claim 9, wherein each of said first portion and said second portion forms a substantially circular loop.

15. A microwave sensor assembly in accordance with claim 14, wherein a diameter of said first portion is different than a diameter of said second portion.

16. A microwave sensor assembly in accordance with claim 9, wherein said emitter further comprises an inner portion, said first portion and said second portion substantially enclose said inner portion.

17. A microwave sensor assembly in accordance with claim 16, wherein said inner portion is capacitively coupled to said first portion and to said second portion when the at least one microwave signal is transmitted through said inner portion.

18. A method for measuring a proximity of a machine component relative to an emitter, said, method comprising:
transmitting at least one microwave signal to the emitter, wherein the emitter includes:
a first portion;
a second portion; and
a connecting portion coupling the first portion to the second portion, wherein the first portion and the second portion generate an electromagnetic field when at least one microwave signal is received;
generating an electromagnetic field from the at least one microwave signal;
generating a loading signal representative of a disruption of the electromagnetic field; and
calculating the proximity of the machine component to the emitter based on the loading signal.

19. A method in accordance with claim 18, wherein the emitter includes an inner portion, said method further comprises capacitively coupling the inner portion to the first portion and to the second portion when the at least one microwave signal is transmitted through the inner portion.

20. A method in accordance with claim 18, wherein said transmitting at least one microwave signal to the emitter comprises transmitting at least one microwave signal through the first portion in a first direction, and transmitting the at least one microwave signal through the second portion in a second direction different from the first direction.
